(19) United States
(12) Patent Application Publication
(10) Pub. No.: US 2008/0128720 A1
(43) Pub. Date: Jun. 5, 2008

(54) Light emitting device

(76) Inventors: Hyun Kyong Cho, Seoul (KR); Sun Kyung Kim, Seoul (KR); Jun Ho Jang, Seoul (KR); Yong Hee Lee, Seoul (KR)

Correspondence Address: MCKENNA LONG & ALDRIDGE LLP;Song K. Jung, 1900 K Street, N.W., Washington, DC, 20006, US

(21) Appl. No.: 11/998,411

(22) Filed: Nov. 30, 2007

(30) Foreign Application Priority Data
Nov. 30, 2006 (KR) 10-2006-0119887

(51) Int. Cl. H01L 33/00

(52) U.S. Cl. 257/95; 257/E33.032

(57) ABSTRACT

A light emitting device is closed. More particularly, a light emitting device capable improving light-extraction efficiency is disclosed. The light emitting device includes a plurality of layers including a reflector layer. The reflector layer has the maximum reflectivity at an incidence angle more than zero degrees and less than an angle θ. The angle θ is represented by the equation θ=Sin⁻¹[n₂/n₁] (where, n₁ is the maximum refractive index of the plurality of layers constituting the light emitting device, and n₂ is the refractive index of an external background material).

This application claims the benefit of the Korean Patent Application No. P2006-0119887, filed on Nov. 30, 2007, which is hereby incorporated by reference as if fully set forth herein.

### BACKGROUND OF THE INVENTION

1. Field of the Invention

The present invention relates to a light emitting device, and more particularly, to a light emitting device capable of improving light-extraction efficiency thereof.

2. Discussion of the Related Art

A light emitting diode (LED) is a well-known semiconductor light emitting device that converts electric current into light beams. Since a red LED using a GaAsP compound semiconductor was commercially available in 1962, it has been used, together with a GaP:N-based green LED, as an image-display light source of electronic apparatuses including telecommunication apparatuses.

The light-extraction efficiency of the semiconductor LED is generally no more than several percent because of a great difference between the refractive index of semiconductor and the refractive index of air or epoxy as a medium finally transmitting light beams.

For example, in the case of an InAlGaAs red LED, it has a critical angle of about 25 degrees, in consideration of the refractive indices of an uppermost GaP layer of the LED and an epoxy region provided for the purpose of surface protection. In this case, if there exists no loss from absorption in materials and thus, multiple reflection can be allowed, the extraction efficiency of light beams, which can be detected in the epoxy region, is about 4.7%.

The remaining light beams are caught in the LED by total internal reflection. Thereby, the light beams may be absorbed into a GaAs substrate through a lower layer of the LED, or may be gradually reduced in strength by a medium, such as quantum wells, that can cause loss from absorption. As a result, the light beams vanish without having an effect on the light-extraction efficiency.

For this reason, there is a need for a solution to extract light beams generated from an LED to the outside efficiently.

### SUMMARY OF THE INVENTION

Accordingly, the present invention is directed to a light emitting device that substantially obviates one or more problems due to limitations and disadvantages of the related art.

An object of the present invention is to provide a light emitting device, which can achieve improved light extraction efficiency with the use of a reflector layer and/or light extracting structure.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a light emitting device having a multi-layer structure, comprising: a reflector layer having the maximum reflectivity at an incidence angle more than zero degrees and less than an angle θ, wherein the angle θ is represented by the equation θ=Sin⁻¹[n₂/n₁] (where, n₁ is the maximum refractive index of the multi-layers constituting the light emitting device, and n₂ is the refractive index of an external background material).

In accordance with another aspect of the present invention, there is provided a light emitting device comprising: a reflector layer including a first semiconductor layers and a second semiconductor layer stacked one above another alternately, the first and second semiconductor layers having different refractive indices from each other; and a third semiconductor layer disposed on the reflector layer and having a thickness thicker than a thickness of the first semiconductor layer or the second semiconductor layer.

In accordance with yet another aspect of the present invention, there is provided a light emitting device comprising: a reflector layer; and a light emitting layer disposed on the reflector layer, wherein the reflector layer has the maximum reflectivity when light emitted from the light emitting layer is incident on the reflector layer by an angle more than zero degrees and less than 25 degrees.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view illustrating a light emitting device according to a first embodiment of the present invention;

FIG. 2 is a diagrammatic view illustrating the vertical light extraction of the light emitting device;

FIG. 3 is a diagrammatic view illustrating the horizontal light extraction of the light emitting device;

FIGS. 4 and 5 are sectional views illustrating a second embodiment of the present invention,

FIG. 4 being a sectional view illustrating a reflector layer on a substrate; and

FIG. 5 being a sectional view illustrating a light emitting device structure on the reflector layer;

FIGS. 6 and 7 are sectional views illustrating a third embodiment of the present invention,

FIG. 6 being a sectional view illustrating a reflector layer on a substrate; and

FIG. 7 being a sectional view illustrating a light emitting device structure on the reflector layer;

FIG. 8 is a graph illustrating the reflectivity of the reflector layer according to the present invention;

FIG. 9 is a graph illustrating the reflected energy of the reflector layer according to the present invention;

FIG. 10 is a graph illustrating the reflectivity at the incidence angle to achieve the maximum reflectivity according to the present invention; and

FIGS. 11 and 12 are graphs illustrating the reflectivity according to the change of the thickness of the reflector layer.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

The present invention may, however, be embodied in many alternate forms and should not be construed as limited to the embodiments set forth herein. Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims

It will be understood that, when an element such as a layer, region or substrate is referred to as being “on” another element, it can be directly on the other element or intervening elements may also be present. It will also be understood that if part of an element, such as a surface, is referred to as “inner,” it is farther from the outside of the device than other parts of the element.

In addition, relative terms, such as “beneath” and “overlies”, may be used herein to describe one layer's or region's relationship to another layer or region as illustrated in the figures.

It will be understood that these terms are intended to encompass different orientations of the device in addition to the orientation depicted in the figures. Finally, the term “directly” means that there are no intervening elements. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms.

The above terms first, second, etc. are used simply to discriminate any one element, component, region, layer, or area from other elements, components, regions, layers, or areas. Accordingly, the term first region, first layer, first area, etc., which will be described hereinafter, may be replaced by the term second region, second layer, or second area.

### FIRST EMBODIMENT

For example, in the case of an InAlGaAs red light emitting device (LED), it has a critical angle of about 25 degrees, in consideration of the refractive indices of an uppermost GaP layer of the LED and an epoxy region provided for the purpose of surface protection. In this case, if there exists no loss from absorption in materials and thus, multiple reflection can be allowed, and also, no mirror, such as a distributed Bragg reflector layer (DBR), is provided underneath the LED, the extraction efficiency of light beams, which can be detected in the epoxy region, is about 4.7%.

The remaining light beams are caught in the LED by total internal reflection. Thereby, the light beams may be absorbed into a GaAs substrate through a lower layer of the LED, or may be gradually reduced in strength by a medium, such as quantum wells, that can cause loss from absorption. As a result, the light beams vanish without having an effect on the light-extraction efficiency.

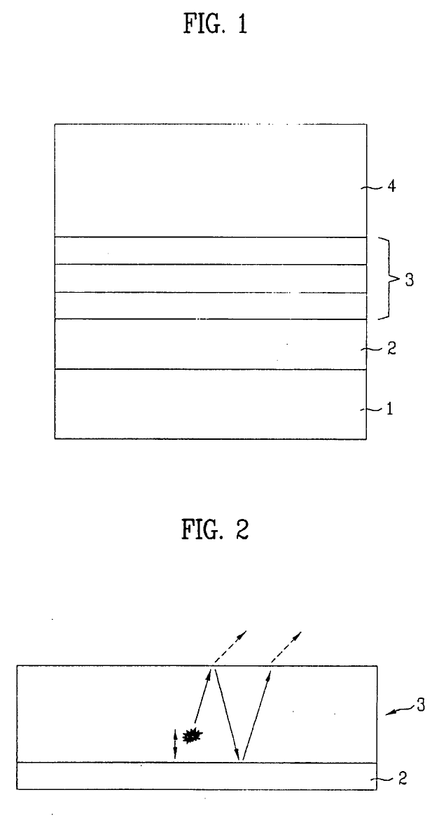

Under the above described situation, a solution to improve the light-extraction efficiency, as shown in FIG. 1, is to provide an LED structure with a distributed Bragg reflector (DBR) layer as a lower layer.

FIG. 1 illustrates an InAlGaAs red LED structure 3 including a distributed Bragg reflector layer 2 grown on a GaAs substrate 1 according to a first embodiment of the present invention.

Here, the distributed Bragg-reflector layer 2 is a combination of an AlAs layer and an Al_{0.5}Ga_{0.5}As layer, each having a thickness of λ/4n (n: the refractive index of each medium) and being used in a vertical-cavity-surface-emitting-laser (VCSEL).

Upon calculation of the contribution of the distributed Bragg reflector layer 2, first, the total light-extraction efficiency can be divided into vertical extraction efficiency and horizontal extraction efficiency. The vertical extraction efficiency can be calculated from the amount of light beams that reach an epoxy region by passing through an uppermost GaP layer. In the present embodiment, the vertical extraction efficiency is about 4.7%.

However, in the case of the red LED structure 3, the GaP layer 4 has no loss from absorption in a visible ray region and occupies most of the volume of the red LED structure 3. Therefore, it is expected that the horizontal extraction efficiency of light beams emitted through a lateral surface of the red LED structure 3 also has a great value.

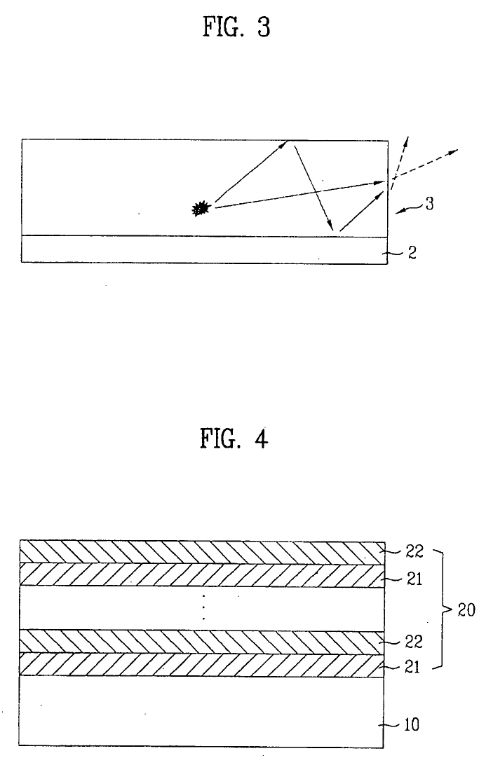

FIGS. 2 and 3 are diagrammatic views provided to calculate the vertical extraction efficiency and the horizontal extraction efficiency when using the distributed Bragg reflector layer 2.

If an ideal reflector capable of reflecting 100% of light beams is provided in a lower layer of an LED structure, a ratio of the vertical extraction efficiency to the horizontal extraction efficiency will be 1:2. Accordingly, with regard to the fact that the reflectivity of a metal-mirror is about 80%, the actual improvement of the light-extraction efficiency, including the vertical extraction efficiency and the horizontal extraction efficiency, caused by the use of the distributed Bragg reflector layer 2, is about 7.3%.

As described above, although it is true that the distributed Bragg reflector layer improves the light-extraction efficiency, the distributed Bragg reflector layer has a limit in the improvement of the light-extraction efficiency.

### SECOND EMBODIMENT

As shown in FIG. 4, a reflector layer 20 is disposed on a substrate 10, to improve the light-extraction efficiency of a light emitting device. The reflector layer 20 includes a plurality of first semiconductor layers 21 and second semiconductor layers 22, which are stacked one above another alternately.

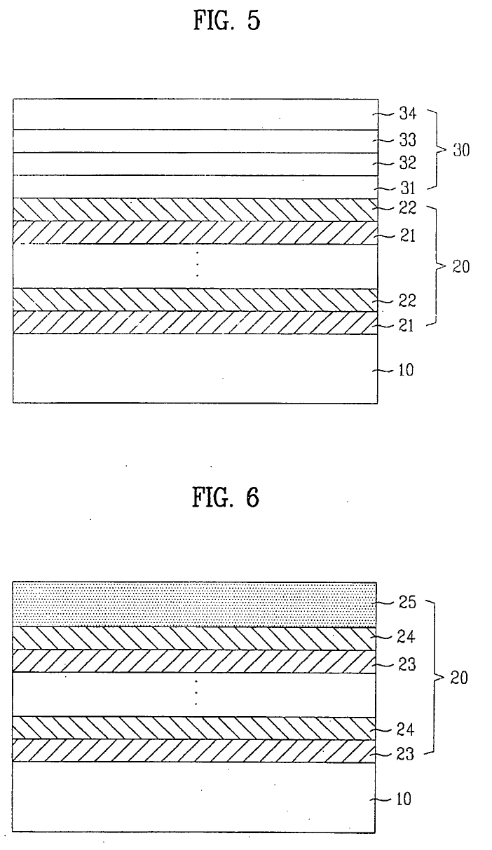

As shown in FIG. 5, a light emitting device structure 30 including an active layer 32 is formed on the reflector layer 20.

In the present embodiment, for example, the substrate 10 is an n-type GaAs substrate. In this case, the first semiconductor layer 21 of the reflector layer 20 may be an AlAs layer, and the second semiconductor layer 22 may be an AlGaAs layer.

More particularly, the first semiconductor layer 21 may be made of AlₓGa₁₋ₓAs or (AlₓGa₁₋ₓ)_{y}In_{1-y}P, and the second semiconductor layer 22 may be made of Al_{y}Ga_{1-y}As or Al_{z}In_{1-z}P. Here, x, y, and z represent a composition ratio of a material, and satisfy the relationship of 0≦x, y, z≦1.

The light emitting device structure 30 formed on the reflector layer 20 may include a first conductive layer 31, the active layer 32, and second conductive layers 33 and 34.

The first conductive layer 31 may be an n-type InAlP layer. Also, the second conductive layers include a p-type InAlP layer 33 and a p-type GaP layer 34. That is, these conductive layers 31, 33, and 34 may be InAlGaP-based semiconductor layers.

Also, the first semiconductor layer 21 and the second semiconductor layer 22 of the reflector layer 20 may be n-type semiconductor layers.

The first semiconductor layer 21 and the second semiconductor layer 22 of the reflector layer 20 have different refractive indices from each other. More specifically, one of the first and second semiconductor layers 21 and 22 has a higher refractive index than that of the other semiconductor layer.

In this case, each layer has a thickness of λ/4n (where, λ is the natural emission wavelength of an active layer, and n is the refractive index of a constituent material of each layer).

Here, the incidence angle of light to achieve the maximum reflectivity of the reflector layer 20 may have a certain value except for 90 degrees. That is, the incidence angle of light to achieve the maximum reflectivity of the reflector layer 20 can be adjusted, to allow the total flux of light beams, which were emitted from a light emitting device and reflected by the reflector layer 20, to have the maximum value at a predetermined distance from the light emitting device.

The incidence angle of light to achieve the maximum reflectivity of the reflector layer 20 is advantageously more than zero degrees and less than an angle θ. Here, the angle θ can be represented by the equation θ=Sin⁻¹[n₂/n₁], (where n₁ is the maximum refractive index of the plurality of layers constituting the light emitting device, and n₂ is the refractive index of an external background material).

In the embodiment of the present invention, the angle θ may be 25 degrees. With the maximum reflectivity derived from the incidence angle of light, the light-extraction efficiency of the light emitting device can be improved greatly.

Meanwhile, a light extracting structure may be formed at a light emitting surface of the light emitting device structure 30 including the first conductive layer 31, the active layer 32, and the second conductive layers 33 and 34 above the reflector layer 20.

Specifically, the light extracting structure can be formed on the second conductive layer 34 and have a unit cell pattern. Generally, a unit cell has a hole or column shape.

In the present invention, the pattern of the light extracting structure may be any one of a square-lattice, triangular-lattice, Archimedean, quasi-crystal, pseudo-random, and roughened surface pattern, or a combination thereof.

Preferably, a distance between the centers of the respective unit cells of the pattern of the light extracting structure or the average distance is in a range of 700 nm to 1500 nm.

As occasion demands, the light extracting structure may be formed on an additional light extracting layer located on the second conductive layer 34.

### THIRD EMBODIMENT

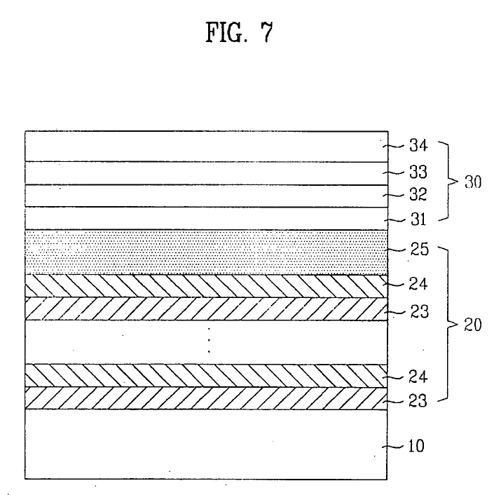

As shown in FIG. 6, the reflector layer 20 formed on the substrate 10 includes a plurality of third semiconductor layers 23 and fourth semiconductor layers 24, which are stacked one above another alternately, and a fifth semiconductor layer 25 located above the alternately stacked third and fourth semiconductor layers 23 and 24.

The thickness of the fifth semiconductor layer 25 is preferably an odd multiple of the thickness of the third semiconductor layer 23 or the fourth semiconductor layer 24, and more preferably, three or more times the thickness of the third semiconductor layer 23 or the fourth semiconductor layer 24.

The thickness of the third semiconductor layer 23 or the fourth semiconductor layer 24 is determined such that the incidence angle of light to achieve the maximum reflectivity of the reflector layer 20 is more than zero degrees and less than an angle θ similar to the second embodiment. In addition, the fifth semiconductor layer 25, which has the thickness of an odd multiple of the third semiconductor layer 23 or the fourth semiconductor layer 24, can be provided to form an uppermost layer of the reflector layer 20.

Here, the angle θ can be represented by the equation θ=Sin⁻¹[n₂/n₁], where n₁ is the maximum refractive index of the plurality of layers constituting the light emitting device, and n₂ is the refractive index of an external background material.

In the embodiment of the present invention, the angle θ may be 25 degrees. With the maximum reflectivity derived from the incidence angle of light, the light-extraction efficiency of the light emitting device can be improved greatly.

Meanwhile, the thickness of the fifth semiconductor layer 25 may have a value obtained by adding or subtracting an error value to or from a thickness of an odd multiple of the third semiconductor layer 23 or the fourth semiconductor layer 24.

In this case, the error value is preferably smaller than 25% the thickness of the third semiconductor layer 23 or the fourth semiconductor layer 24, in consideration of a thickness difference between the third semiconductor layer 23 or the fourth semiconductor layer 24 and the fifth semiconductor layer 25.

As shown in FIG. 7, the light emitting device structure 30 including the active layer 32 is formed on the reflector layer 20.

In the present embodiment, for example, the substrate 10 is an n-type GaAs substrate. In this case, the third semiconductor layer 23 of the reflector layer 20 may be an AlAs layer, and the fourth semiconductor layer 24 may be an AlGaAs layer.

More particularly, the third semiconductor layer 23 may be made of AlₓGa₁₋ₓAs or (AlₓGa₁₋ₓ)_{y}In_{1-y}P, and the fourth semiconductor layer 24 may be made of Al_{y}Ga_{1-y}As or Al_{z}In_{1-z}P. Here, x, y, and z represent a composition ratio of a material, and satisfy the relationship of 0≦x, y, z≦1.

The light emitting device structure 30 formed on the reflector layer 20, similar to the second embodiment, may include the first conductive layer 31, the active layer 32, and the second conductive layers 33 and 34.

The first conductive layer 31 may be an n-type InAlP layer, and the second conductive layers may include the p-type InAlP layer 33 and the p-type GaP layer 34. That is, these conductive layers may be InAlGaP-based semiconductor layers. Also, it will be appreciated that InAlGaAs-based semiconductor layers may be used.

Also, the third semiconductor layer 23 and the fourth semiconductor layer 24 of the reflector layer 20 may be n-type semiconductor layers.

Meanwhile, similar to the second embodiment, the light extracting structure may be formed at a light emitting surface of the light emitting device structure 30. Specifically, the light extracting structure can be formed on the second conductive layer 34 and have a unit cell pattern. Generally, a unit cell has a hole or column shape.

In the present invention, the pattern of the light extracting structure may be any one of a square-lattice, triangular-lattice, Archimedean, quasi-crystal, pseudo-random, and roughened surface pattern, or a combination thereof.

Preferably, a distance between the centers of the respective unit cells of the pattern of the light extracting structure or the average distance is in a range of 700 nm to 1500 nm.

As occasion demands, the light extracting structure may be formed on an additional light extracting layer located on the second conductive layer 34.

Hereinafter, the effects of the present invention according to the first to third embodiments of the present invention will be described in detail.

In the case of a red light emitting device in which a reflector layer has the maximum reflectivity under the condition of a vertical incidence angle, the total light-extraction efficiency in vertical and horizontal directions is about 7.3%.

As described above with relation to the third embodiment of the present invention, the vertical extraction efficiency can be improved by changing the thickness of each layer constituting the reflector layer 20. More specifically, the thickness of each layer of the reflector layer 20 can be changed such that the incidence angle of light to achieve the maximum reflectivity of the reflector layer 20 is in a range from zero degrees to a critical angle. Here, zero degrees is a value of a vertical incidence angle.

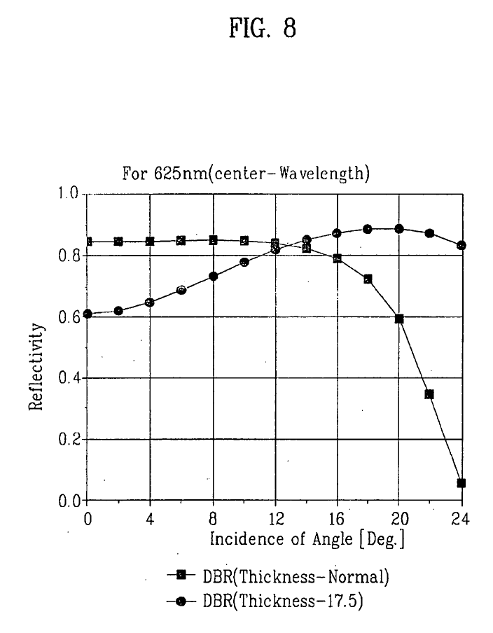

For example, as shown in FIG. 8, under the assumption that the center wavelength of an InAlGaAs red light emitting device is 625 nm, when comparing the reflectivity of a first reflector layer (See. square-dotted line), which has the maximum reflectivity at the vertical incidence angle, with the reflectivity of a second reflector layer (See. circular dotted line) which has the maximum reflectivity at an angle of 17.5 degrees, it could be found that the first reflector layer, which has the maximum reflectivity at the vertical incidence angle, is gradually reduced in reflectivity as the incidence angle increases from the vertical direction as the peak point, whereas the second reflector layer, which has the maximum reflectivity at the incidence angle of 17.5 degrees, is gently reduced in reflectivity in opposite directions from the peak point of 17.5 degrees that could be expected.

More specifically, the reflector layer, which has the maximum reflectivity at the vertical incidence angle, has a rapid reduction of reflectivity starting from the incidence angle of about 16 degrees. As compared to the reflector layer having the maximum reflectivity in the vertical direction, the reflector layer of the present invention, which is adjusted in thickness, has a feature that the reflectivity has a gentle reduction in proportion to an increase of the incidence angle.

Considering the energy efficiency in consideration of an area occupied by the incidence angle, it can be expected that the reflector layer 20 of the present invention, having the adjusted thickness, can achieve a greater average reflectivity.

The thickness of the reflector layer suitable to achieve the maximum light-extraction efficiency in the vertical direction will be described as follows. First, it can be analogized that an area corresponding to the given incidence angle θ is proportional to sin θ, and the optimized thickness is a value set to achieve the maximum reflectivity at an angle larger than a half of the critical angle.

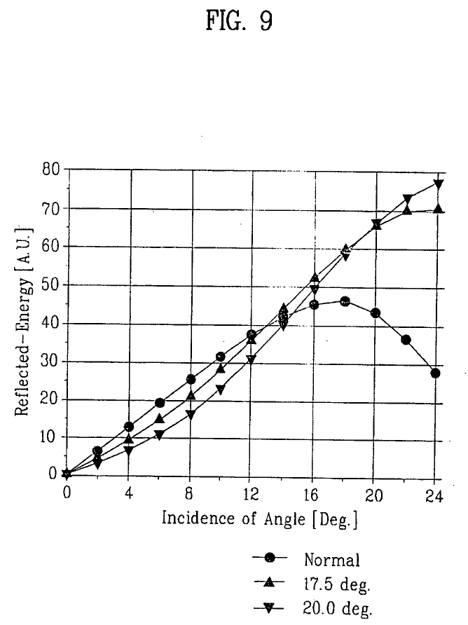

On the basis of the above analogy, the reflectivity can be calculated in due consideration of the effect of the area while changing the thickness of each layer of the reflector layer 20. As a result, as shown in FIG. 9, it can be appreciated that, when the thickness of each layer of the reflector layer 20 is set such that the maximum reflectivity can be achieved at the incidence angle of 17.5 degrees, the reflectivity can be increased up to a maximum of 33%, as compared to the case using the reflector layer which has the maximum reflectivity at the vertical incidence angle.

The reason why the horizontal extraction efficiency is lower than the vertical extraction efficiency is that the reflector layer exhibits a low reflectivity when the incidence angle excessively deviates from a central angle. However, considering the fact that the AlAs layer (i.e. the first semiconductor layer 21) as the first layer of the reflector layer 20 has a smaller refractive index (n=3.13) than a refractive index (n=3.29) of the first conductive layer 31, i.e. the InAlP layer of the light emitting device structure 30 adjacent to the reflector layer 20, the total internal reflection between the two layers 21 and 31 can be anticipated.

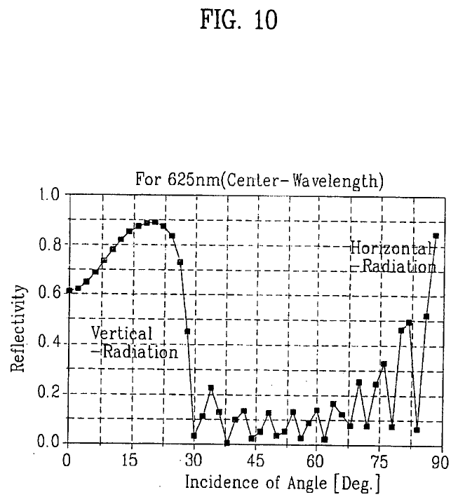

However, as shown in FIG. 10, it can be appreciated that the reflector layer still exhibits a low reflectivity even under the incidence angle that causes the total internal reflection. This is because an evanescent wave, which is caused upon the total internal reflection, is coupled with the Al_{0.5}Ga_{0.5}As(n=3.55) layer next to the AlAs layer, and results in evanescent wave tunneling. This phenomenon is generally called “frustrated-total-internal-reflection (FTIR)”.

The magnitude of the evanescent wave is reduced exponentially with respect to a direction perpendicular to a boundary surface. Therefore, when the thickness of the AlAs layer is sufficiently larger than the wavelength of light, the evanescent wave tunneling by the FTIR will vanish.

Accordingly, to increase the thickness of the AlAs layer, i.e. the first layer of the reflector layer while maintaining the interference condition of light, it is proposed to satisfy the equation t′=(2s+1)t (where, s is a natural number including zero, and t is a thickness to achieve the maximum reflectivity in the vertical direction).

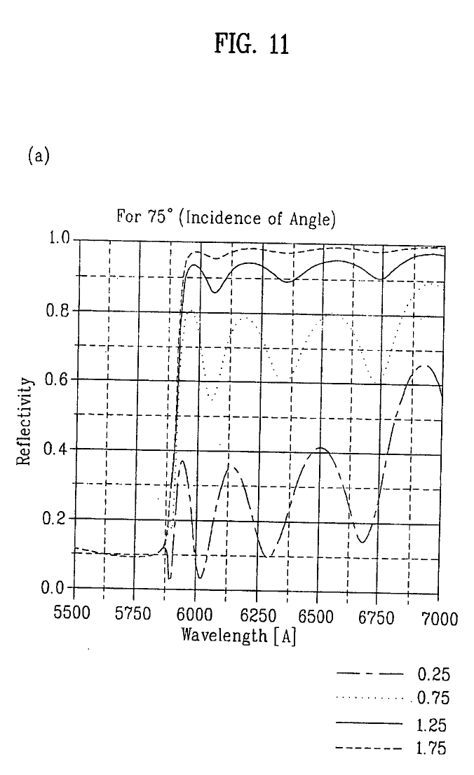

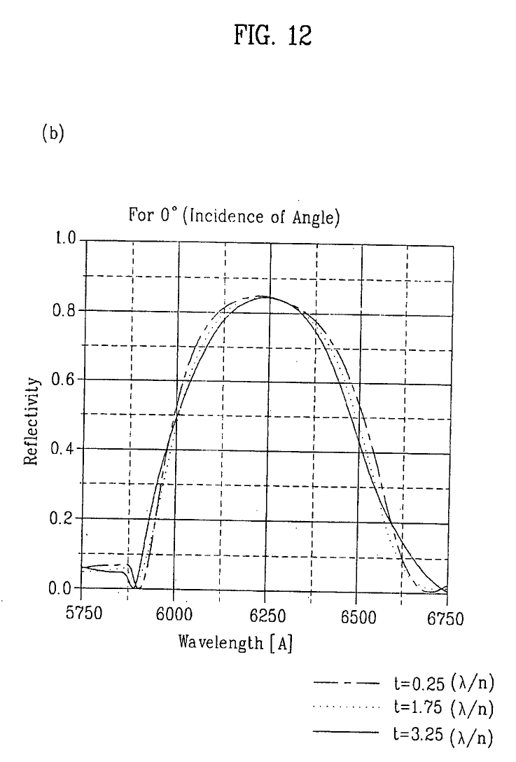

It can be appreciated from FIGS. 11 and 12 that the greater the thickness of each layer of the reflector layer 20, the greater the reflectivity that can be expected.

FIGS. 11 and 12 illustrate the reflectivity according to the change of the thickness of each layer under the incidence angle of 75 degrees and under the incidence angle of zero degrees, respectively. It can be appreciated from FIGS. 11 and 12 that almost the complete total internal reflection can occur under the condition of t′=7t or more.

It can be also appreciated that increasing the thickness of the AlAs layer, i.e. the first layer of the reflector layer 20 has substantially no effect on the reflectivity at the vertical incidence angle.

Also, it is possible to calculate the actual horizontal extraction efficiency when the first semiconductor (AlAs) layer of the reflector layer 20 has a sufficient thickness to ignore FTIR. It can be expected that, if the critical angle θ, defined by the relationship of the AlAs layer of the reflector layer 20 and the first conductive layer 31 (i.e. InAlP layer) of the light emitting device structure 30 adjacent to the reflector layer 20, is larger than 72 degrees measured on the basis of a normal vector, light beams within the critical angle θ can be extracted in a lateral direction without loss from absorption.

However, it should be noted that the light beams extracted in the lateral direction may pass through a relatively long path as compared to the vertical direction, and therefore, only one dispersion procedure is assumed. In this case, the final horizontal extraction efficiency is about 7.8%. This results in an improvement of about 6.5 times that of the prior art horizontal extraction efficiency.

When considering all the above described results, it can be concluded that the incidence angle to achieve the maximum reflectivity of the reflector layer 20 must be more than zero degrees and less than the angle θ for the sake of improved vertical extraction efficiency, and the angle θ is represented by the equation θ=Sin⁻¹[n₂/n₁] (where n₁ is the maximum refractive index of the plurality of layers constituting the light emitting device, and n₂ is the refractive index of an external background material).

In another aspect, if the incidence angle to achieve the maximum reflectivity of the reflector layer 20 is preferably in a range from zero degrees to 25 degrees, and more preferably, is 17.5 degrees for the sake of improved vertical extraction efficiency, and the thickness of the first layer of the reflector layer 20 is more than seven times that of other layers for the sake of improved horizontal extraction efficiency, the total extraction efficiency can be improved by about 1.8 times.

Meanwhile, when forming a light extracting structure on a light emitting surface of the light emitting device, a further improvement in the light-extraction efficiency can be accomplished.

The following Table 1 represents measured results of the light-extraction efficiency by the first to third embodiments of the present invention, which selectively use the reflector layer 20 and the light extracting structure.

Here, the measured results are given based on the conditions that the size of a light emitting device chip is 1.0 mm wide and 1.0 mm long, and an integrating sphere packaged is used. Also, the applied current is 350 mA.

Also, the light extracting structure is applied onto the second conductive layer 34, and the unit cell has a hole shape. The resulting hole has a diameter of 800 nm and a depth of about 1 μm, and a period as a distance between the centers of the holes is 1200 nm.

TABLE 1

| | | Increase of Extraction | | |
|---|---|---|---|---|
| | | Efficiency | | |
| | | | Light | |
| | | | Extracting | |
| Structure | Pₒ [mW] | Total | Structure | Vₒₚ [V] |
| DBR | 32.4 (2.77) | 1 | N/A | 2.20 (0.10) |
| Reflector | 54.4 (1.15) | 1.7 | 1 | 2.18 (0.09) |
| Layer | | | | |
| Reflector | 67.8 (0.8) | 2.1 | 1.25 | *2.65 (0.09) |
| Layer + Light | | | | |
| Extracting | | | | |
| Structure | | | | |

As represented in Table 1, assuming that the light-extraction efficiency measured by packaging the light emitting device having the above described configuration of the first embodiment is 1, it could be appreciated that the light-extraction efficiency of the light emitting device having the reflector layer according to the second embodiment is improved up to 1.7 times.

Also, it could be appreciated that, in consideration of the increment of lightness prior to and after using the light extracting structure, the use of the light extracting structure causes an improvement of the light-extraction efficiency 1.25 times as compared to the case of using only the reflector layer.

Accordingly, it could be appreciated that the light-extraction efficiency of the light emitting device structure having the light extracting structure according to the third embodiment is improved up to 2.1 times. In Table 1, Pₒ represents consumed electricity, Vₒₚ represents an operating voltage, and bracketed numbers represent standard deviations of measured lightness.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A light emitting device having a multi-layer structure, comprising:
a reflector layer having the maximum reflectivity at an incidence angle more than zero degrees and less than an angle θ,
wherein the angle θ is represented by the equation θ=Sin⁻¹[n₂/n₁] (where, n₁ is the maximum refractive index of the multi-layers constituting the light emitting device, and n₂ is the refractive index of an external background material).

2. The light emitting device according to claim 1, wherein the reflector layer comprises a plurality of first semiconductor layers and second semiconductor layers stacked one above another alternately, the first and second semiconductor layers having different refractive indices from each other.

3. The light emitting device according to claim 2, wherein the first semiconductor layer is an AlAs layer, and the second semiconductor layer is an AlGaAs layer.

4. The light emitting device according to claim 2, wherein the first semiconductor layer is made of AlₓGa₁₋ₓAs or (AlₓGa₁₋ₓ)_{y}In_{1-y}P, and the second semiconductor layer is made of Al_{y}Ga_{1-y}As or Al_{z}In_{1-z}P (where, x, y, and z represent a composition ratio of a material, and satisfy the relationship of 0≦x, y, z≦1).

5. The light emitting device according to claim 2, wherein the light emitting device further comprises a third semiconductor layer disposed on the reflector layer and having a thickness thicker than a thickness of the first semiconductor layer or the second semiconductor layer.

6. The light emitting device according to claim 5, wherein the third semiconductor layer includes a single layer or a plurality of layers.

7. The light emitting device according to claim 5, wherein the third semiconductor layer is made of the same material as that of one of the first semiconductor layer and the second semiconductor layer.

8. The light emitting device according to claim 1, wherein the reflector layer is disposed on a substrate.

9. The light emitting device according to claim 8, wherein the substrate is a GaAs substrate

10. The light emitting device according to claim 1, wherein the light emitting device further comprises:
a first conductive layer disposed on the reflector layer;
a light emitting layer disposed on the first conductive layer; and
a second conductive layer disposed on the light emitting layer.

11. The light emitting device according to claim 10, wherein a light extracting structure having a unit cell pattern is formed on the second conductive layer.

12. The light emitting device according to claim 11, wherein the pattern of the light extracting structure is one of a square-lattice, triangular-lattice, Archimedean, quasi-crystal, pseudo-random, and roughened surface pattern, or a combination thereof.

13. The light emitting device according to claim 11, wherein a distance between the centers of unit cells of the pattern of the light extracting structure or the average distance is in a range of 700 nm to 1500 nm.

14. The light emitting device according to claim 1, wherein a light extracting structure is formed at a light emitting surface of the light emitting device.

15. A light emitting device comprising:
a reflector layer including a first semiconductor layer and a second semiconductor layer stacked one above another alternately, the first and second semiconductor layers having different refractive indices from each other; and
a third semiconductor layer disposed on the reflector layer and having a thickness thicker than a thickness of the first semiconductor layer or the second semiconductor layer.

16. The light emitting device according to claim 15, wherein the thickness of the third semiconductor layer has a value obtained by adding or subtracting an error value to or from a thickness of an odd multiple of the first semiconductor layer or the second semiconductor layer, and the error value is smaller than 25% the thickness of the first semiconductor layer or the second semiconductor layer.

17. The light emitting device according to claim 15, wherein the thickness of the third semiconductor layer is three or more times the thickness of the first semiconductor layer or the second semiconductor layer.

18. The light emitting device according to claim 15, wherein the reflector layer has the maximum reflectivity at an incidence angle more than zero degrees and less than an angle θ, and the angle θ is represented by the equation θ=Sin⁻¹[n₂/n₁] (where, n₁ is the maximum refractive index of the plurality of layers constituting the light emitting device, and n₂ is the refractive index of an external background material).

19. The light emitting device according to claim 15, wherein a light extracting structure is disposed at a light emitting surface of the light emitting device, and has a spatially variable refractive index.

20. A light emitting device comprising:
a reflector layer; and
a light emitting layer disposed on the reflector layer,
wherein the reflector layer has the maximum reflectivity when light emitted from the light emitting layer is incident on the reflector layer by an angle more than zero degrees and less than 25 degrees.
